(19) United States
(12) Patent Application Publication
(10) Pub. No.: US 2015/0037915 A1
(43) Pub. Date: Feb. 5, 2015

(54) METHOD AND SYSTEM FOR LASER FOCUS PLANE DETERMINATION IN A LASER SCRIBING PROCESS

(71) Applicants: Wei-Sheng LEI, San Jose, CA (US); Brad Eaton, Menlo Park, CA (US); Apama IYER, Sunnyvale, CA (US); Madhava Rao Yalamanchili, Morgan Hill, CA (US); Ajay Kumar, Cupertino, CA (US)

(72) Inventors: Wei-Sheng LEI, San Jose, CA (US); Brad Eaton, Menlo Park, CA (US); Apama IYER, Sunnyvale, CA (US); Madhava Rao Yalamanchili, Morgan Hill, CA (US); Ajay Kumar, Cupertino, CA (US)

(21) Appl. No.: 14/035,402

(22) Filed: Sep. 24, 2013

Related U.S. Application Data
(60) Provisional application No. 61/860,796, filed on Jul. 31, 2013.

(51) Int. Cl. H01L 21/78; B23K 26/03; B23K 26/04; B23K 26/06

(52) U.S. Cl. CPC H01L 21/78; B23K 26/0661; B23K 26/032; B23K 26/046
USPC 438/16; 156/345.24; 219/121.68

(57) ABSTRACT

In embodiments, a method of laser scribing a mask disposed over a semiconductor wafer includes determining a height of the semiconductor over which a mask layer is disposed prior to laser scribing the mask layer. In one embodiment the method includes: determining a height of the semiconductor wafer under the mask in a dicing street using an optical sensor and patterning the mask with a laser scribing process. The laser scribing process focuses a scribing laser beam at a plane corresponding to the determined height of the semiconductor wafer in the dicing street. Examples of determining the height of the semiconductor wafer can include directing a laser beam to the dicing street of the semiconductor wafer, which is transmitted through the mask and reflected from the wafer, and identifying an image on a surface of the wafer under the mask with a camera.

### PRIORITY

This application is a Non-Provisional of, claims priority to, and incorporates by reference in its entirety for all purposes, the U.S. Provisional Patent Application No. 61/860,796 filed Jul. 31, 2013.

### BACKGROUND

1) Field

Embodiments of the present invention pertain to the field of semiconductor processing and, in particular, to methods of laser scribing semiconductor wafers.

2) Description of Related Art

In semiconductor wafer processing, integrated circuits are formed on a wafer (also referred to as a substrate) composed of silicon or other semiconductor material. In general, layers of various materials which are either semiconducting, conducting or insulating are utilized to form the integrated circuits. These materials are doped, deposited and etched using various well-known processes to form integrated circuits. Each wafer is processed to form a large number of individual regions containing integrated circuits known as dice or dies.

Following the integrated circuit formation process, the wafer is “diced” to separate the individual die from one another for packaging or for use in an unpackaged form within larger circuits. The two main techniques that are used for wafer dicing are scribing and sawing. With scribing, a diamond tipped scribe is moved across the wafer surface along pre-formed scribe lines. These scribe lines extend along the spaces between the dies. These spaces are commonly referred to as “streets.” The diamond scribe forms shallow scratches in the wafer surface along the streets. Upon the application of pressure, such as with a roller, the wafer separates along the scribe lines. The breaks in the wafer follow the crystal lattice structure of the wafer substrate. Scribing can be used for wafers that are about 10 mils (thousandths of an inch) or less in thickness. For thicker wafers, sawing is presently the preferred method for dicing.

With sawing, a diamond tipped saw rotating at high revolutions per minute contacts the wafer surface and saws the wafer along the streets. The wafer is mounted on a supporting member such as an adhesive film stretched across a film frame and the saw is repeatedly applied to both the vertical and horizontal streets. One problem with either scribing or sawing is that chips and gouges can form along the severed edges of the dice. In addition, cracks can form and propagate from the edges of the dies into the substrate and render the integrated circuit inoperative. Chipping and cracking are particularly a problem with scribing because only one side of a square or rectangular die can be scribed in the direction of the crystalline structure. Consequently, cleaving of the other side of the die results in a jagged separation line. Because of chipping and cracking, additional spacing is required between the dies on the wafer to prevent damage to the integrated circuits, e.g., the chips and cracks are maintained at a distance from the actual integrated circuits. As a result of the spacing requirements, not as many dies can be formed on a standard sized wafer and wafer real estate that could otherwise be used for circuitry is wasted. The use of a saw exacerbates the waste of real estate on a semiconductor wafer. The blade of the saw is approximate 15 microns thick. As such, to insure that cracking and other damage surrounding the cut made by the saw does not harm the integrated circuits, three to five hundred microns often must separate the circuitry of each of the dies. Furthermore, after cutting, each die requires substantial cleaning to remove particles and other contaminants that result from the sawing process.

Plasma dicing has also been used, but may have limitations as well. For example, one limitation hampering implementation of plasma dicing may be cost. A standard lithography operation for patterning resist may render implementation cost prohibitive. Another limitation possibly hampering implementation of plasma dicing is that plasma processing of commonly encountered metals (e.g., copper) in dicing along streets can create production issues or throughput limits.

### SUMMARY

One or more embodiments of the invention are directed to methods of dicing a semiconductor wafer including laser scribing a mask disposed over the semiconductor wafer. In one embodiment, the laser scribing can be followed by a plasma etch to dice the wafer.

In one embodiment, a method of laser scribing a mask disposed over a semiconductor wafer includes determining a height of a semiconductor wafer under the mask in a dicing street using an optical sensor. The method includes patterning the mask with a laser scribing process. The laser scribing process focuses a scribing laser beam at a plane corresponding to the determined height of the semiconductor wafer in the dicing street.

In one embodiment, a method includes directing a laser beam to a dicing street of the semiconductor wafer, the laser beam to be transmitted through the mask and reflect from a layer disposed under the mask. The method includes detecting, with an optical sensor, a height of the layer disposed under the mask based on the reflected laser beam. The method includes determining a height of the semiconductor wafer in the dicing street based on the detected height of the layer disposed under the mask. The method further includes patterning the mask with a laser scribing process. The laser scribing process focuses a scribing laser beam at a plane corresponding to the determined height of the semiconductor wafer in the dicing street.

In one embodiment, a system for laser scribing a mask disposed over a semiconductor wafer includes a laser source to direct a laser beam to a dicing street of the semiconductor wafer, the laser beam to be transmitted through the mask and reflect from a layer disposed under the mask. The system includes an optical sensor to detect a height of the layer disposed under the mask based on the reflected laser beam. The system includes a processor to determine a height of the semiconductor wafer in the dicing street based on the detected height of the layer disposed under the mask. The system also includes a laser scribing module to pattern the mask with a laser scribing process. The laser scribing process is to focus a scribing laser beam at a plane corresponding to the determined height of the semiconductor wafer in the dicing street.

### BRIEF DESCRIPTION OF THE DRAWINGS

Embodiments of the present invention are illustrated by way of example, and not by way of limitation, and can be more fully understood with reference to the following detailed description when considered in connection with the figures in which:

FIG. 1a illustrates laser scribing a semiconductor wafer with a focal plane at the wafer surface, in accordance with an embodiment of the present invention;

FIG. 1b illustrates a system for laser scribing a semiconductor wafer as in FIG. 1a with a focal plane at the wafer surface, in accordance with an embodiment of the present invention;

FIG. 2 is a flowchart representing operations in a method of laser scribing a mask in accordance with an embodiment of the present invention;

FIGS. 3A and 3B illustrate cross-sectional views of a semiconductor wafer including a plurality of integrated circuits before and after laser scribing, in accordance with embodiments of the present invention;

FIG. 4 illustrates a cross-sectional view of a stack of materials that may be present in a street region of a semiconductor wafer, in accordance with embodiments of the present invention;

FIG. 5 illustrates a plan view schematic of an integrated dicing system in accordance with an embodiment of the present invention; and

FIG. 6 illustrates a block diagram of an exemplary computer system which controls automated performance of one or more operation in the methods described herein, in accordance with an embodiment of the present invention.

### DETAILED DESCRIPTION

Apparatuses, systems, and methods of laser scribing a mask layer over a substrate are described. Laser scribing may be used in applications such as integrated circuit dicing. For example, a laser scribing process may be used to remove a mask layer, organic and inorganic dielectric layers, and/or device layers disposed over a semiconductor wafer or substrate. A subsequent plasma etch may be implemented to etch through the bulk of the wafer or substrate to yield die or chip singulation or dicing.

According to an embodiment, during the laser scribing process, a laser beam removes a mask layer, a passivation layer, and/or device layers to expose the silicon substrate for subsequent plasma etching. Focusing the scribing laser beam at the wafer surface facing laser irradiation (instead of, for example, focusing the laser beam on top of a mask layer) results in higher process quality. Higher process quality resulting from focusing the laser beam at the wafer surface is due, at least in part, to the greater sensitivity of device layers to laser processing conditions than mask layers. For example, device layers, which can include dielectric materials, can be more susceptible to delamination and cracking than mask layers. Thus, a method and apparatus to precisely place the laser focus plane on the wafer surface has the potential to improve dicing yield. However, accurately determining the laser focus plane of the wafer is difficult due to, for example, variations in wafer thickness, dicing tape thickness, and/or mask thickness.

For example, for a nominally 50 μm thick silicon wafer, the wafer thickness variation can be approximately ±10 μm from wafer to wafer. For a 400 μm wafer, the wafer thickness variation can be approximately ±20 μm from wafer to wafer. Regarding dicing tape thickness variation, for nominally 90 μm thick dicing tape, the tape thickness variation can be approximately ±10 μm. Furthermore, different tapes having different thicknesses can be used resulting in further variations (e.g., a 10% thickness variation may be typical for different tapes). Regarding mask layers, the thickness variation of a mask layer depends on nominal mask thickness and wafer surface conditions (e.g., bump height, bump density, and other factors affecting wafer surface conditions).

Therefore, in one example, a nominally 50 μm thick wafer mounted on a tape frame can have a total thickness variation of up to 40 μm from wafer to wafer due to variations in wafer and tape thicknesses. Additionally, access to the thickness variations of wafers and tapes of other nominal thicknesses is limited. Such wide variations in wafer, tape, and mask thickness can result in inaccurate laser focusing. Inaccurate laser focusing due to such difficulties may cause non-uniform laser scribing kerf width and/or scribing depth, which affects dicing quality. Other thickness variations which are greater than or less than the abovementioned ranges can also result in reduced yields when performing laser scribing according to existing methods.

According to one embodiment, a method includes determining a height of a wafer in a dicing street with an infrared laser, and patterning a mask disposed over the wafer with a laser scribing process with a focus plane at the determined wafer height in the dicing street.

In the following description, numerous specific details are set forth, such as laser and plasma etch wafer dicing approaches in order to provide a thorough understanding of embodiments of the present invention. It will be apparent to one skilled in the art that embodiments of the present invention may be practiced without these specific details. In other instances, well-known aspects, such as integrated circuit fabrication, are not described in detail in order to not unnecessarily obscure embodiments of the present invention. Furthermore, it is to be understood that the various embodiments shown in the Figures are illustrative representations and are not necessarily drawn to scale.

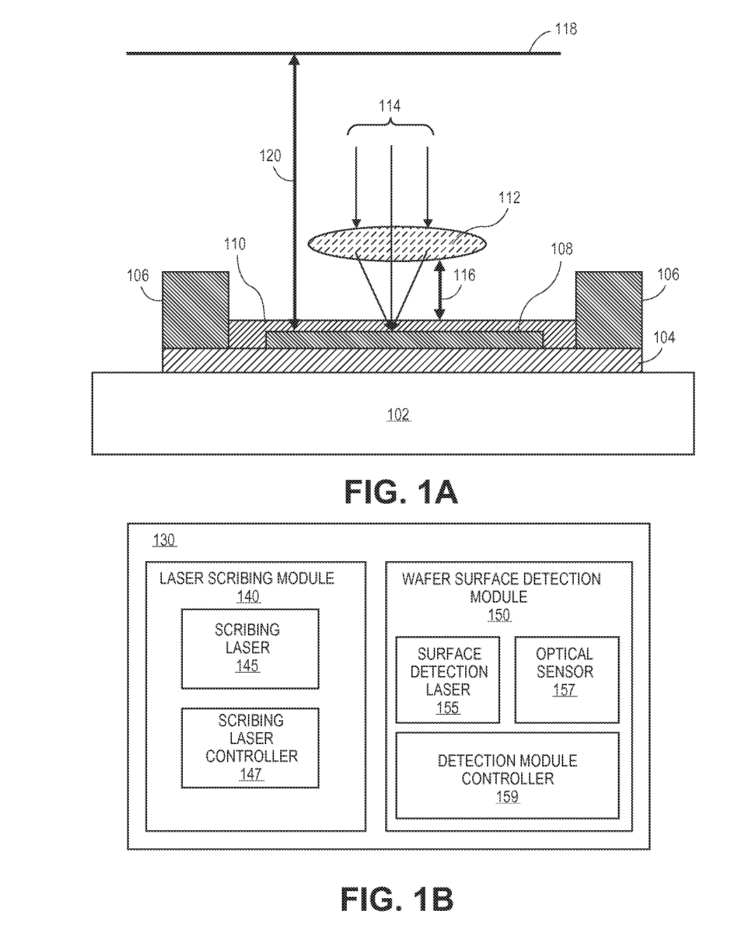

FIG. 1a illustrates laser scribing a semiconductor wafer with a focal plane at the wafer surface using the exemplary system in FIG. 1b, in accordance with an embodiment of the present invention. As mentioned above, the laser scribing described herein can be used in a wafer dicing method.

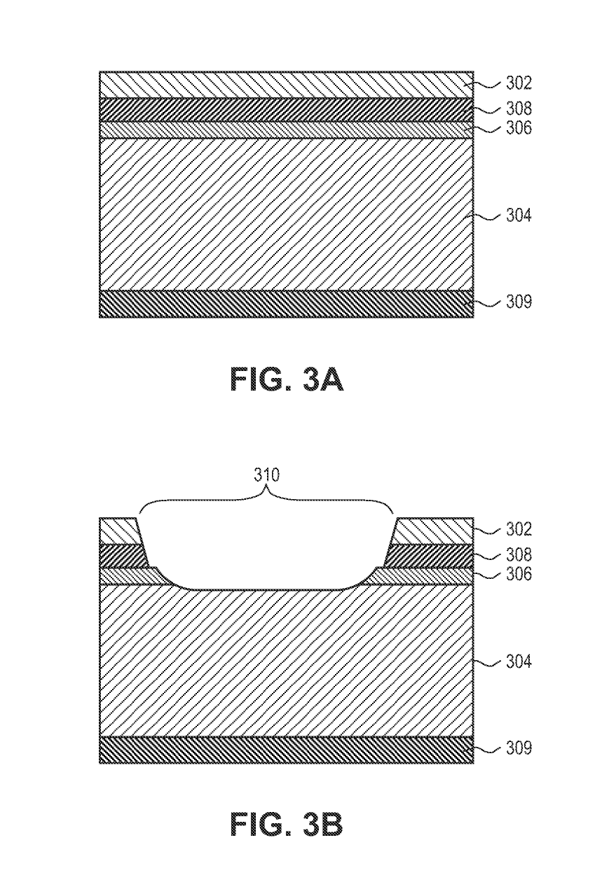

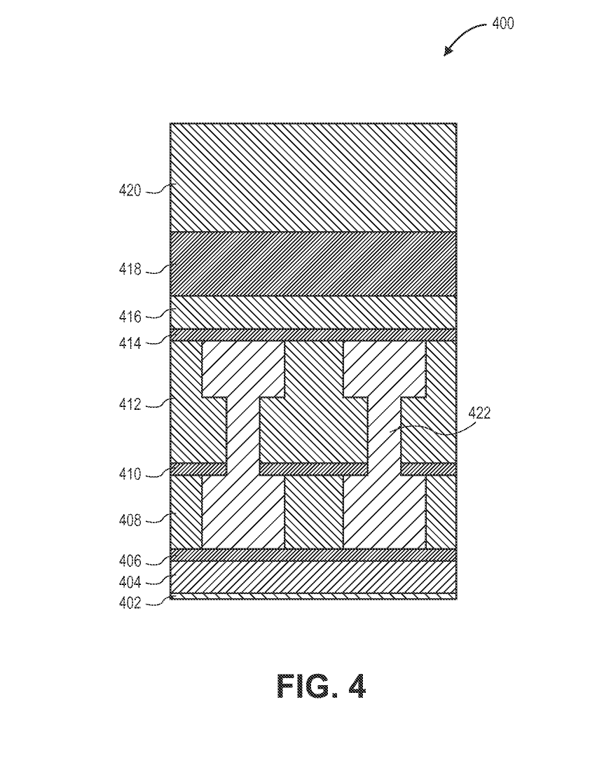

In the embodiment illustrated in FIG. 1a, a chuck 102 holds a sample 108. The chuck 102 can be any suitable chuck for holding a substrate or wafer during processing. For example, the chuck 102 can be a Johnsen-Rahbeck, coulombic electrostatic chuck (ESC), or other ESC to hold the sample 108. The sample 108 can include a semiconductor wafer or substrate over which one or more other layers are disposed. For example, the sample 108 can include a wafer as illustrated in FIG. 3A, FIG. 3B, and FIG. 4. As will be described in greater detail below, FIGS. 3A and 3B illustrate cross-sectional views of a semiconductor wafer including a substrate layer, an integrated circuit or device layer, and a passivation layer. FIG. 4 illustrates a cross-sectional view of a stack of materials that may be used in a street region of a semiconductor wafer or substrate. Although the sample 108 may include multiple layers as in FIGS. 3A, 3B, and 4, for simplicity, the sample 108 is depicted as a single layer.

The sample 108 can be disposed on dicing tape 104 and supported by a frame 106. Other embodiments may not include the dicing tape 104 and frame 106 as depicted in FIG. 1a. Disposed above the sample 108 is a mask 110 which covers and protects integrated circuits (ICs) formed on the semiconductor wafer. An example of a mask is the frontside mask 302 of FIG. 3a described below.

FIG. 1b illustrates an example of a scribing laser system 130. The system 130 includes a scribing laser source (e.g., a micromachining laser) that produces a scribing laser beam 114, which the system 130 directs through a focus lens 112 to the sample 108. The scribing laser beam 114 is focused with the focus lens 112 at a working distance 116 from the surface of the mask layer 110. As described above, it can be beneficial to focus the scribing laser beam 114 at the surface of the wafer (in contrast to, for example, focusing the scribing laser 114 at the surface of the mask layer 110). To focus the scribing laser at the surface of the wafer, the system 130 determines the height of the surface of the wafer.

To determine the height of the surface of the wafer, the system 100 employs a wafer surface detection module 150. The wafer surface detection module can include a surface detection laser 155 and a vision module or optical sensor 157. The wafer surface detection module can also include a detection module controller 159 to control operation of the surface detection laser 155 and the optical sensor 157. For example, the controller 159 controls the parameters of the surface detection laser 155 and controls when the surface detection laser 155 and the optical sensor 157 are operating. According to one embodiment, the surface detection laser 155 emits a laser beam that reflects from the surface of the wafer. The surface detection laser 155 can emit a laser beam having a wavelength in the visible spectrum, the ultra-violet (UV), or infra-red (IR) ranges (the three totaling a broadband optical spectrum). The optical sensor 157 detects the reflected laser beam. The wafer surface detection module 150 determines the surface height based on the time between the emission and detection of the reflected laser beam and the laser triangulation principle. The “height” of the wafer surface can be measured from a reference point or plane 118. The reference point or plane 118 can also be referred to as a homing position.

In an embodiment employing a laser to detect the wafer height, the mask layer 110 disposed above the wafer is formed from a material that permits transmission of the detection laser beam. Thus, the detection laser is transmitted through the mask layer 110 disposed over the wafer, and reflected from a layer under the mask layer. For example, the mask layer 110 can be formed from PVA. In one such embodiment, an infrared laser detection beam is transmitted through a PVA mask layer and reflected from the wafer surface.

Although a laser-based wafer surface detection module 150 is illustrated in FIG. 1b, the system 130 can employ other optical systems. For example, the optical sensor can include a camera detecting light in the visible spectrum, or any other suitable optical sensor. In one embodiment, the system employs a camera to automatically search for and identify an image plane of a target. For example, a camera system can search for an alignment mark or a test pattern on the wafer surface along the dicing street of device wafers. Alignment marks typically have a short height (e.g., having a submicron height), so the thickness of alignment marks can be ignored in determining the position of image plane. The system can then use the position of the identified image plane, and compute the wafer surface height based on the identified image plane (e.g., using triangulation principles).

According to embodiments, the system performs the wafer height measurements in a dicing street. The system 130 can use the wafer surface detection module 150 to measure the height of the wafer surface at several different locations in the dicing streets on a wafer to get an average height of wafer surface. Performing measurements in the dicing street can result in more accurate measurements because dies can include layers with bumps (e.g., up to 50 μm bumps). The dicing streets typically do not include large bumps such as those on other areas of the wafer. Therefore, taking measurements of the height of the wafer surface in the dicing street can avoid inaccurate readings resulting from the bumps on each die. However, other embodiments may include measuring the wafer height at other areas of the wafer without large bumps.

In one embodiment, the height of the semiconductor wafer surface obtained by the wafer surface detection module 150 is the desired laser focus plane. Thus, the system 150 reports the determined height of the wafer surface to a scribing laser controller 147 of a laser scribing module 140. The scribing laser controller can adjust the focus plane of a scribing laser 145 from wafer to wafer based on the determined height of the wafer. After adjusting the focus plane at the wafer surface, the scribing laser 145 scribes the wafer. Note that although the modules are illustrated separately for clarity, other configurations are possible. For example, a single controller can encompass logic to control the scribing laser 145, the surface detection laser 155, and/or the optical sensor 157.

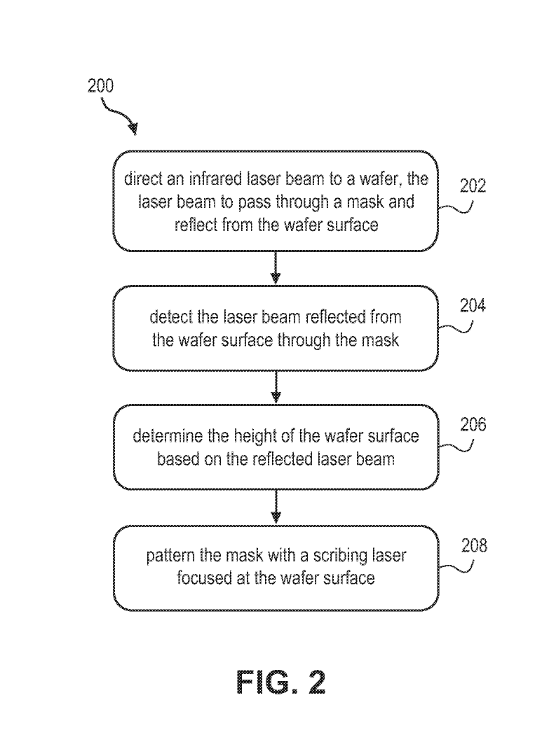

FIG. 2 is a flowchart representing operations in a method of laser scribing a mask in accordance with an embodiment of the present invention. The method 200 begins with a laser detection system (e.g., the wafer surface detection module 150 of FIG. 1b) directing a laser beam to a dicing street of the semiconductor wafer at operation 202. For example, the laser detection system directs the laser at a sample such as those depicted in FIGS. 3A and 4 in a dicing street. The laser beam is to be transmitted through the mask and reflect from the semiconductor surface disposed under the mask. An optical sensor detects the reflected laser beam at operation 204. The laser detection system can perform operations 202 and 204 one or more times. If the laser detection system performs multiple measurements, the system can take an average of the performed measurements. At operation 206, the system determines the height of the semiconductor wafer in the dicing street based on the reflected laser beam. At operation 208, a scribing laser patterns the mask with a laser scribing process. The laser scribing process focuses a scribing laser beam at a plane corresponding to the determined height of the semiconductor wafer in the dicing street.

FIGS. 3A and 3B illustrate cross-sectional views of a semiconductor wafer including a plurality of integrated circuits before and after performance of a method of laser scribing the semiconductor wafer in accordance with embodiments of the present invention. The samples in FIGS. 3A and 3B include a front side mask 302 formed above a semiconductor wafer or substrate 304. According to one embodiment, the semiconductor wafer or substrate 304 has a diameter of at least 300 mm and has a thickness of 300 μm to 800 μm. In one embodiment, the semiconductor substrate 304 has a diameter of 10 μm to 800 μm. As illustrated, in an embodiment, the mask is a conformal mask. Conformal mask embodiments advantageously ensure sufficient thickness of the mask over an underlying topography (e.g., 20 μm bumps, not shown) to survive the duration of a plasma etch dicing operation. In alternative embodiments, however, the mask is a non-conformal, planarized mask (e.g., thickness of the mask over a bump is less than thickness of the mask in a valley). Formation of a conformal mask may be by CVD, for example, or by any other process known in the art. In one embodiment, the mask 302 covers and protects integrated circuits (ICs) formed on the surface of semiconductor wafer and also protects bump projecting or protruding up 10-20 μm from the surface of the semiconductor wafer. The mask 302 also covers intervening streets formed between adjacent ones of the integrated circuits.

In accordance with an embodiment of the present invention, forming the mask 302 includes forming a layer such as, but not limited to, a water-soluble layer (PVA, etc.) that permits transmission of a laser beam or other light source (e.g., a laser emitted by surface detection laser 155 of FIG. 1b) for determining the height of the wafer surface. The mask 302 can also include a photo-resist layer, and/or an I-line patterning layer. For example, a polymer layer such as a photo-resist layer may be composed of a material otherwise suitable for use in a lithographic process. In embodiments with multiple mask layers, a water-soluble base coat may be disposed below a non-water-soluble overcoat. The basecoat then provides a means of stripping the overcoat while the overcoat provides plasma etch resistance and/or for good mask ablation by the laser scribing process. It has been found for example, that mask materials transparent to the laser wavelength employed in the scribing process contribute to low die edge strength. Hence, a water-soluble base coat, of PVA, for example, as the first mask material layer, may function as a means of undercutting a plasma-resistant/laser energy absorbing overcoat layer of the mask so that the entire mask may be removed/lifted off from the underlying integrated circuit (IC) thin film layer. The water-soluble base coat may further serve as a barrier protecting the IC thin film layer from the process used to strip the energy absorbing mask layer. In embodiments, the laser energy absorbing mask layer is UV-curable and/or UV absorbing, and/or green-band (500-540 nm) absorbing. Exemplary materials include many photo-resists and polyimide (PI) materials conventionally employed for passivation layers of IC chips. In one embodiment, the photo-resist layer is composed of a positive photo-resist material such as, but not limited to, a 248 nanometer (nm) resist, a 193 nm resist, a 157 nm resist, an extreme ultra-violet (EUV) resist, or a phenolic resin matrix with a diazonaphthoquinone sensitizer. In another embodiment, the photo-resist layer is composed of a negative photo-resist material such as, but not limited to, poly-cis-isoprene and poly-vinyl-cinnamate.

The semiconductor wafer or substrate 304 has disposed thereon or therein, as a portion of the integrated circuits 306, an array of semiconductor devices. Examples of such semiconductor devices include, but are not limited to, memory devices or complimentary metal-oxide-semiconductor (CMOS) transistors fabricated in a silicon substrate and encased in a dielectric layer. A plurality of metal interconnects may be formed above the devices or transistors, and in surrounding dielectric layers, and may be used to electrically couple the devices or transistors to form the integrated circuits. Conductive bumps and passivation layers 308 may be formed above the interconnect layers. Materials making up the streets may be similar to or the same as those materials used to form the integrated circuits. For example, streets may be composed of layers of dielectric materials, semiconductor materials, and metallization. In one embodiment, one or more of the streets includes test devices similar to the actual devices of the integrated circuits.

FIG. 3B illustrates the sample of 3A after laser scribing. The laser scribing process is performed generally to remove the material of the streets present between the integrated circuits 306, although embodiments of the invention may apply to other laser scribing applications. In accordance with an embodiment of the present invention, patterning the mask 302 with the laser scribing process includes forming trenches 310 partially into the regions of the semiconductor wafer between the integrated circuits. In an embodiment, patterning the mask with the laser scribing process includes direct writing a pattern using a laser having a pulse width in the femtosecond range.

Specifically, a scribing laser with a wavelength in the visible spectrum or the ultra-violet (UV) or infra-red (IR) ranges (the three totaling a broadband optical spectrum) may be used to provide a femtosecond-based laser, i.e., a laser with a pulse width on the order of the femtosecond (10⁻¹⁵ seconds). In one embodiment, ablation is not, or is essentially not, wavelength dependent and is thus suitable for complex films such as films of the mask, the streets and, possibly, a portion of the semiconductor wafer or substrate.

Laser parameters selection, such as pulse width, may be critical to developing a successful laser scribing and dicing process that minimizes chipping, microcracks, and delamination in order to achieve clean laser scribe cuts. The cleaner the laser scribe cut, the smoother an etch process that may be performed for ultimate die singulation. In semiconductor device wafers, many functional layers of different material types (e.g., conductors, insulators, semiconductors) and thicknesses are typically disposed thereon. Such materials may include, but are not limited to, organic materials such as polymers, metals, or inorganic dielectrics such as silicon dioxide and silicon nitride.

A street between individual integrated circuits disposed on a wafer or substrate may include the similar or same layers as the integrated circuits themselves. For example, FIG. 4 illustrates a cross-sectional view of a stack of materials that may be used in a street region of a semiconductor wafer or substrate, in accordance with an embodiment of the present invention. Referring to FIG. 4, a street region 400 includes the top portion 402 of a silicon substrate, a first silicon dioxide layer 404, a first etch stop layer 406, a first low K dielectric layer 408 (e.g., having a dielectric constant of less than the dielectric constant of 4.0 for silicon dioxide), a second etch stop layer 410, a second low K dielectric layer 412, a third etch stop layer 414, an undoped silica glass (USG) layer 416, a second silicon dioxide layer 418, and a layer of photo-resist 420 or some other mask. Copper metallization 422 is disposed between the first and third etch stop layers 406 and 414 and through the second etch stop layer 410. In a specific embodiment, the first, second and third etch stop layers 406, 410 and 414 are composed of silicon nitride, while low K dielectric layers 408 and 412 are composed of a carbon-doped silicon oxide material.

Under conventional scribing laser irradiation (such as nanosecond-based or picosecond-based laser irradiation), the materials of street 400 may behave quite differently in terms of optical absorption and ablation mechanisms. For example, dielectrics layers such as silicon dioxide, is essentially transparent to all commercially available laser wavelengths under normal conditions. By contrast, metals, organics (e.g., low K materials) and silicon can couple photons very easily, particularly in response to nanosecond-based or picosecond-based laser irradiation. In an embodiment, however, a femtosecond-based laser process is used to pattern a layer of silicon dioxide, a layer of low K material, and a layer of copper by ablating the layer of silicon dioxide prior to ablating the layer of low K material and the layer of copper. In a specific embodiment, pulses of approximately less than or equal to 400 femtoseconds are used in a femtosecond-based laser irradiation process to remove a mask, a street, and a portion of a silicon substrate. In one embodiment, pulses of approximately less than or equal to 500 femtoseconds are used.

In accordance with an embodiment of the present invention, suitable femtosecond-based scribing laser processes are characterized by a high peak intensity (irradiance) that usually leads to nonlinear interactions in various materials. In one such embodiment, the femtosecond laser sources have a pulse width approximately in the range of 10 femtoseconds to 500 femtoseconds, although preferably in the range of 100 femtoseconds to 400 femtoseconds. In one embodiment, the femtosecond laser sources have a wavelength approximately in the range of 1570 nanometers to 200 nanometers, although preferably in the range of 540 nanometers to 250 nanometers. In one embodiment, the laser and corresponding optical system provide a focal spot at the work surface approximately in the range of 3 microns to 15 microns, though preferably approximately in the range of 5 microns to 10 microns.

The spatial beam profile of the scribing laser at the work surface may be a single mode (Gaussian) or have a shaped top-hat profile. In an embodiment, the scribing laser source has a pulse repetition rate approximately in the range of 200 kHz to 10 MHz, although preferably approximately in the range of 500 kHz to 5 MHz. In an embodiment, the laser source delivers pulse energy at the work surface approximately in the range of 0.5 μJ to 100 μJ, although preferably approximately in the range of 1 μJ to 5 θJ. In an embodiment, the laser scribing process runs along a work piece surface at a speed approximately in the range of 500 mm/sec to 5 m/sec, although preferably approximately in the range of 600 mm/sec to 2 m/sec.

The scribing process may be run in single pass only, or in multiple passes, but, in an embodiment, preferably 1-2 passes. In one embodiment, the scribing depth in the work piece is approximately in the range of 5 microns to 50 microns deep, preferably approximately in the range of 10 microns to 20 microns deep. The scribing laser may be applied either in a train of single pulses at a given pulse repetition rate or a train of pulse bursts. In an embodiment, the kerf width of the laser beam generated is approximately in the range of 2 microns to 15 microns, although in silicon wafer scribing/dicing preferably approximately in the range of 6 microns to 10 microns, measured at the device/silicon interface.

Scribing laser parameters may be selected with benefits and advantages such as providing sufficiently high laser intensity to achieve ionization of inorganic dielectrics (e.g., silicon dioxide) and to minimize delamination and chipping caused by underlayer damage prior to direct ablation of inorganic dielectrics. Also, parameters may be selected to provide meaningful process throughput for industrial applications with precisely controlled ablation width (e.g., kerf width) and depth. As described above, a femtosecond-based laser is far more suitable to providing such advantages, as compared with picosecond-based and nanosecond-based laser ablation processes. However, even in the spectrum of femtosecond-based laser ablation, certain wavelengths may provide better performance than others. For example, in one embodiment, a femtosecond-based laser process having a wavelength close to or in the UV range provides a cleaner ablation process than a femtosecond-based laser process having a wavelength close to or in the IR range. In a specific such embodiment, a femtosecond-based laser process suitable for semiconductor wafer or substrate scribing is based on a laser having a wavelength of approximately less than or equal to 540 nanometers. In a particular such embodiment, pulses of approximately less than or equal to 400 femtoseconds of the laser having the wavelength of approximately less than or equal to 540 nanometers are used. However, in an alternative embodiment, dual laser wavelengths (e.g., a combination of an IR laser and a UV laser) are used. In one embodiment, plasma etching and die singulation may be performed after the laser scribing process.

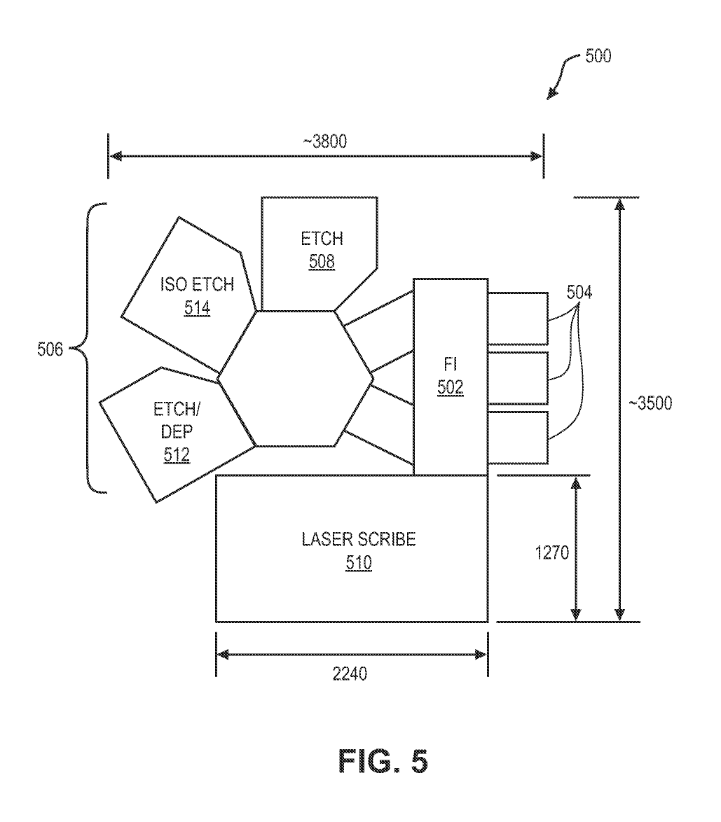

Referring to FIG. 5, a process tool 500 includes a factory interface 502 (FI) having a plurality of load locks 504 coupled therewith. A cluster tool 506 is coupled with the factory interface 502. The cluster tool 506 includes one or more plasma etch chambers, such as anisotropic plasma etch chamber 508 and isotropic plasma etch chamber 514. A laser scribe apparatus 510 is also coupled to the factory interface 502. The overall footprint of the process tool 500 may be, in one embodiment, approximately 3500 millimeters (3.5 meters) by approximately 3800 millimeters (3.8 meters), as depicted in FIG. 5.

In an embodiment, the laser scribe apparatus 510 houses a femtosecond-based laser. The femtosecond-based laser is suitable for performing a laser ablation portion of a hybrid laser and etch singulation process, such as the laser ablation processes described above. In one embodiment, a moveable stage is also included in laser scribe apparatus 500, the moveable stage configured for moving a wafer or substrate (or a carrier thereof) relative to the femtosecond-based laser. In a specific embodiment, the femtosecond-based laser is also moveable. The overall footprint of the laser scribe apparatus 510 may be, in one embodiment, approximately 2240 millimeters by approximately 1270 millimeters, as depicted in FIG. 5. The laser scribe apparatus 510 can also include a laser detection module as described with reference to FIGS. 1a and 1b (or other apparatus for detecting height of a wafer) to direct a laser beam to a dicing street of the semiconductor wafer. The detection laser beam is to be transmitted through the mask and reflect from a layer disposed under the mask. The laser detection module can also include an optical sensor to detect a height of the layer disposed under the mask based on the reflected laser beam. A laser detection module or system can also be embodied elsewhere (e.g., as a separate module).

In an embodiment, the one or more plasma etch chambers 508 is configured for etching a wafer or substrate through the gaps in a patterned mask to singulate a plurality of integrated circuits. In one such embodiment, the one or more plasma etch chambers 508 is configured to perform a deep silicon etch process. In a specific embodiment, the one or more plasma etch chambers 508 is an Applied Centura® Silvia™ Etch system, available from Applied Materials of Sunnyvale, Calif., USA. The etch chamber may be specifically designed for a deep silicon etch used to create singulate integrated circuits housed on or in single crystalline silicon substrates or wafers. In an embodiment, a high-density plasma source is included in the plasma etch chamber 508 to facilitate high silicon etch rates. In an embodiment, more than one etch chamber is included in the cluster tool 506 portion of process tool 500 to enable high manufacturing throughput of the singulation or dicing process.

The factory interface 502 may be a suitable atmospheric port to interface between an outside manufacturing facility with laser scribe apparatus 510 and cluster tool 506. The factory interface 502 may include robots with arms or blades for transferring wafers (or carriers thereof) from storage units (such as front opening unified pods) into either cluster tool 506 or laser scribe apparatus 510, or both.

Cluster tool 506 may include other chambers suitable for performing functions in a method of singulation. For example, in one embodiment, in place of an additional etch chamber, a deposition chamber 512 is included. The deposition chamber 512 may be configured for mask deposition on or above a device layer of a wafer or substrate prior to laser scribing of the wafer or substrate, e.g., by a uniform spin-on process. In one such embodiment, the deposition chamber 512 is suitable for depositing a uniform layer with a conformality factor within approximately 10%.

In embodiments, the isotropic plasma etch chamber 514 is employs a downstream plasma source, such as a high frequency magnetron or inductively coupled source disposed a distance upstream of a process chamber where a substrate is housed during isotropic etch processing described elsewhere herein. In embodiments the isotropic plasma etch chamber 514 is plumbed to use exemplary non-polymerizing plasma etch source gases, such as one or more of NF₃ or SF₆, Cl₂ or SiF₄, and one or more oxidizers, such as O₂.

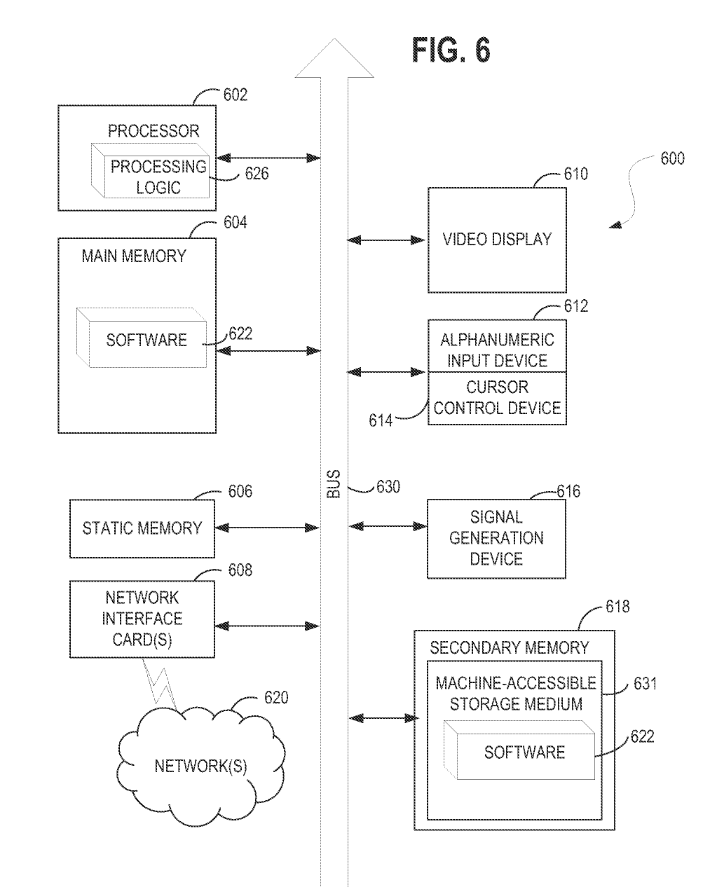

FIG. 6 illustrates a computer system 600 within which a set of instructions, for causing the machine to execute one or more of the scribing methods discussed herein may be executed. The exemplary computer system 600 includes a processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

Processor 602 represents one or more general-purpose processing devices such as a microprocessor, central processing unit, or the like. More particularly, the processor 602 may be a complex instruction set computing (CISC) microprocessor, reduced instruction set computing (RISC) microprocessor, very long instruction word (VLIW) microprocessor, etc. Processor 602 may also be one or more special-purpose processing devices such as an application specific integrated circuit (ASIC), a field programmable gate array (FPGA), a digital signal processor (DSP), network processor, or the like. Processor 602 is configured to execute the processing logic 626 for performing the operations and steps discussed herein.

The computer system 600 may further include a network interface device 608. The computer system 600 also may include a video display unit 610 (e.g., a liquid crystal display (LCD) or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium (or more specifically a computer-readable storage medium) 631 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface device 608.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, optical and magnetic media, and other non-transitory machine-readable storage medium.

Thus, the above description describes a method and system for laser focus plane determination in a laser scribing process. It is to be understood that the above description is intended to be illustrative, and not restrictive. For example, while flow diagrams in the figures show a particular order of operations performed by certain embodiments of the invention, it should be understood that such order is not required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

What is claimed is:

1. A method of laser scribing a mask disposed over a semiconductor wafer, the method comprising:
determining a height of the semiconductor wafer under the mask in a dicing street using an optical sensor; and
patterning the mask with a laser scribing process, the laser scribing process to focus a scribing laser beam at a plane corresponding to the determined height of the semiconductor wafer in the dicing street.

2. The method of claim 1, wherein determining the height of the semiconductor wafer under the mask in the dicing street using the optical sensor comprises:
directing a laser beam to the dicing street of the semiconductor wafer, the laser beam to be transmitted through the mask and reflect from a layer disposed under the mask;
detecting, with the optical sensor, a height of the layer disposed under the mask based on the reflected laser beam; and
determining the height of the semiconductor wafer based on the detected height of the layer disposed under the mask.

3. The method of claim 1, wherein determining the height of the semiconductor wafer under the mask in the dicing street using the optical sensor comprises:
identifying an image on a surface of the semiconductor wafer under the mask with a camera; and
determining the height of the semiconductor wafer based on the identified image.

4. The method of claim 1, wherein patterning the mask further comprises:
patterning a passivation layer and a device layer to expose a substrate layer of the semiconductor wafer.

5. The method of claim 4, further comprising plasma etching the exposed substrate layer.

6. The method of claim 1, wherein patterning the mask further comprises direct writing a pattern with a femtosecond laser having a wavelength less than or equal to 540 nanometers and a laser pulse width less than or equal to 500 femtoseconds.

7. The method of claim 1, wherein the mask further comprises a water-soluble mask layer on the semiconductor wafer.

8. The method of claim 7, wherein the water-soluble mask layer comprises PVA.

9. The method of claim 8, wherein the mask comprises a multi-layered mask comprising the water-soluble mask layer as a base coat and a non-water-soluble mask layer as an overcoat on top of the base coat.

10. The method of claim 9, wherein the non-water-soluble mask layer is a photo-resist or a polyimide (PI).

11. The method of claim 1, wherein the semiconductor wafer has a diameter of at least 300 mm and has a thickness of 10 μm to 800 μm.

12. A method of laser scribing one or more layers disposed over a substrate, the one or more layers comprising a plurality of integrated circuits (ICs) and a mask layer covering the ICs, the method comprising:
directing an infrared laser beam to the one or more layers disposed over the substrate, the infrared laser beam to be transmitted through the mask layer and reflect from a layer disposed under the mask layer in a dicing street;
detecting, with an optical sensor, a height of the layer disposed under the mask layer in the dicing street based on the reflected infrared laser beam;
determining a substrate height in the dicing street based on the detected height of the layer disposed under the mask layer; and
forming a trench in at least the mask layer with a laser scribing process, the laser scribing process to place a laser focus plane on a surface of the substrate based on the determined substrate height in the dicing street.

13. The method of claim 12, further comprising:
forming the trench in a passivation layer and a device layer to expose the substrate.

14. The method of claim 13, further comprising plasma etching the exposed substrate.

15. The method of claim 12, wherein forming the trench in at least the mask layer further comprises direct writing a pattern with a femtosecond laser having a wavelength less than or equal to 540 nanometers and a laser pulse width less than or equal to 500 femtoseconds.

16. A system for laser scribing a mask disposed over a semiconductor wafer, the system comprising:
a laser source to direct a laser beam to a dicing street of the semiconductor wafer, the laser beam to be transmitted through the mask and reflect from a layer disposed under the mask;
an optical sensor to detect a height of the layer disposed under the mask based on the reflected laser beam;
a processor to determine a height of the semiconductor wafer in the dicing street based on the detected height of the layer disposed under the mask; and
a laser scribing module to pattern the mask with a laser scribing process, the laser scribing process to focus a scribing laser beam at a plane corresponding to the determined height of the semiconductor wafer in the dicing street.

17. The system of claim 16, wherein the laser scribing module is to further pattern a passivation layer and a device layer to expose a substrate layer of the semiconductor wafer.

18. The system of claim 16, further comprising a plasma etch chamber to etch the exposed semiconductor wafer.

19. The system of claim 16, wherein the laser scribing module comprises a femtosecond laser to direct write a pattern, the femtosecond laser having a wavelength less than or equal to 540 nanometers and a laser pulse width less than or equal to 500 femtoseconds.

20. The system of claim 16, wherein the mask further comprises a water-soluble mask layer on the semiconductor wafer.
